(19) United States
(12) Patent Application Publication
(10) Pub. No.: US 2003/0182000 A1
(43) Pub. Date: Sep. 25, 2003

(54) Alternative sound track for hearing-handicapped users and stressful environments

(75) Inventors: Hannes Muesch, San Francisco, CA (US); Brent W. Edwards, San Francisco, CA (US); Sunil Puria, Mountain View, CA (US)

Correspondence Address: HAYNES BEFFEL & WOLFELD LLP, P O BOX 366, HALF MOON BAY, CA, 94019, US

(73) Assignee: Sound ID

(21) Appl. No.: 10/104,364

(22) Filed: Mar. 22, 2002

(51) Int. Cl. G06F 17/00; H03G 7/00

(52) U.S. Cl. 700/94; 381/106

(57) ABSTRACT

The present invention includes methods of preprocessing soundtracks adapted to hearing impairment, environmental noise or other factors and making the preprocessed soundtracks available as alternate soundtracks. Particular aspects of the present invention are described in the claims, specification and drawings.

### RELATED APPLICATION DATA

This application is related to the commonly assigned and co-pending U.S. patent application Ser. No. 09/957,344, filed on Sep. 20, 2001, entitled “Sound Enhancement for Mobile Phones and Other Products Producing Personalized Audio for Users,” by inventors R. Scott Rader, Christoph Menzel, Brent Edwards, Sunil Puria, Benny B. Johansen (RXSD 1009-1), which is hereby incorporated by reference as if set forth in full.

### BACKGROUND OF THE INVENTION

1. Field of the Invention

The present invention relates to the field of sound enhancement of a multimedia soundtrack to compensate for hearing impairment, environmental noise or other factors and, more particularly, to preprocessing soundtracks and impressing them on recording media, thereby permitting selection and enjoyment of an enhanced soundtrack based on user, environmental noise or other characteristics with standard playback equipment.

2. Description of Related Art

Adjusting audio signals to compensate for individual and environmental noise factors is important in a variety of contexts. Many individuals have flat or sloped hearing impairments, which change their threshold for perceiving audio signals. See, e.g., Minifie et al., Normal Aspects of Speech, Hearing, and Language (“Psychoacoustics”, Arnold M. Small, pps. 343-420), 1973, Prentice-Hall, Inc.; Lippmann et al., “Study of Multichannel Amplitude Compression and Linear Amplification for Persons with Sensorineural Hearing Loss,” J. Acoust. Soc. Am. 69(2) (February 1981). Multi-band amplitude compression is one approach to raising relatively faint audio signals above an individual's perception threshold, without causing the discomfort or distortions associated with simple amplification. Environmental factors also require compensation. Research suggests that broadband noise masks speech much the same as some forms of hearing impairment. Braida et al., “Review of Recent Research on Multiband Amplitude Compression for the Hearing Impaired,” in: Studebaker, G. A., Bess, F. H., eds. The Vanderbilt Hearing-Aid Report, Upper Darby, Pa.: Monographs in Contemporary Audiology, 1982; 133-40. Travelers on planes, trains and automobiles encounter various background noises characteristic of those modes of transportation.

Delivery of customized audio products, based on individual hearing profiles for impaired hearing clients, has been proposed in the commonly owned and copending U.S. patent application Ser. No. 09/464,036, filed Dec. 15, 1999, by Pluvinage, et al., entitled “System and Method for Producing and Storing Hearing Profiles and Customized Audio Data Based on Such Hearing Profiles.”

Development of listener-specific devices and audio signals has been discussed, e.g., for use of compression in phones is described in Goldberg (U.S. Pat. No. 4,829,565) and Allen & Youtkas (U.S. Pat. No. 5,553,134), primarily for noise compensation. Other patents include: U.S. Pat. Nos. 5,802,164, 5,539,806, 6,061,431, 5,737,719, 5,388,185, 5,896,449 for telephone signal enhancement; U.S. Pat. Nos. 4,964,304, 6,071,236, 3,974,335, and 5,737,389 for hearing testing over a phone or telecommunications network.

Both the encoding and signal processing approaches described above require customization that reduces their application. Accordingly, there is an opportunity to introduce a generalized approach that does not require special hardware, taking advantage of new capabilities of multimedia formats for alternate soundtracks.

### SUMMARY OF THE INVENTION

The present invention includes methods of preprocessing soundtracks adapted to hearing impairment, environmental or other factors and making the preprocessed soundtracks available as alternate soundtracks. Particular aspects of the present invention are described in the claims, specification and drawings.

### BRIEF DESCRIPTION OF THE DRAWINGS

FIG. 1 is a graph showing hearing impairment and noise thresholds.

FIGS. 2a-c are graphs showing various techniques for combining hearing threshold and noise parameters.

FIG. 3 is a conceptual block diagram showing the sound processing to prepare an audio track according to aspects of the present invention.

FIG. 4 is a high-level flowchart of a method practicing aspects of the present invention.

### DETAILED DESCRIPTION

The following detailed description is made with reference to the figures. Preferred embodiments are described to illustrate the present invention, not to limit its scope, which is defined by the claims. Those of ordinary skill in the art will recognize a variety of equivalent variations on the description that follows.

Alternative preprocessed soundtracks can be implemented on a variety of media, including DVDs and CDs. DVD discs provide up to 17 GB of storage with higher than CD-ROM transfer rates, with the same overall size as a standard 120 mm diameter, 1.2 mm thick CD. DVD disc have access times similar to CD-ROM and presently come in four standard versions: DVD-5 is a single-sided single-layered disc with a capacity of 4.7 GB; DVD-9 is a single-sided double-layered disc offering 8.5 GB; DVD-10 is a 9.4 GB dual-sided single-layered disc; DVD-18 will increase capacity to a huge 17 GB on a dual-sided dual-layered disc. These storage capacities support several formats to which the present invention may be applied.

DVD-Video is a digital storage format for feature-length motion pictures. DVD-Video titles typically support multiple aspect ratios, allowing the viewer to choose from at least a couple, such as 16:9 letterbox, wide-screen formats and a more conventional 4:3 ratio. DVD-Video titles also typically allow the user to choose from up to eight different languages and from 32 different sets of sub-titles. Some of the formats for audio encoding which are or could be used on DVD discs include MPEG-2, Dolby Pro Logic, Dolby AC-3, SDDC, and THX. For a dual layer disc (DVD-9) capacity increases to 240 minutes. A double-sided disc (DVD-10) will hold slightly more at 266 minutes, but the disc may need to be turned over to play the second side. Many DVD movies have taken advantage of double-sided discs by putting a version formatted for a normal TV or monitor with a 4:3 aspect ratio on one side and a wide screen version formatted for a 16:9 aspect ratio on the other.

Additional formats cover other market segments. DVD-ROM is a high-capacity data storage medium. DVD-Audio is an audio-only storage format similar to CD-Audio. DVD-R offers a write-once, read-many storage format akin to CD-R. DVD-RAM was the first rewritable (erasable) flavor of DVD to come to market and has subsequently found competition in the DVD-RW and DVD+RW formats.

Another setting for a multimedia presentation is walking tours, where the visual stimulus is separate from the accompanying audio or soundtrack. As the user moves or changes focus from one aspect to another of an exhibit, different accompanying audios, synchronized to the tour, are invoked. The different audios may be invoked by the user or automatically, by proximity to an object of interest, for instance during a tour. In this sense, tour is not limited to a particular route, but refers to a collection of objects or aspects of the objects for which there is accompanying audio. Manual invocation may be based on a visual stimulus, such as matching the profile of a building or reading an identifier from a sign. An audio track may be synchronized with the visual stimulus by including matching data such as an icon, picture or identifying or descriptive label. Automatic invocation may result from detecting a signal such as a radio (analog or digital, e.g., Bluetooth,) light (infrared or ultraviolet) or sonic (ultrasonic or subsonic) signal that identifies a location. An audio track may be synchronized to the signal by including data that links the audio tracks to the signal or location. Automatic invocation also may result from detecting the user's location based on general locating signals, such as GPS or differential GPS. An audio track may be synchronized to the location by including data that links the audio tracks to the location. For a timed audio presentation, a single accompanying audio may be used and the user may have the normal options of pausing, rewinding or fast forwarding through the accompanying audio. Aspects of the present invention can be applied to generate one or more alternative audio tracks that are adapted to hearing loss, environmental noise and other auditory factors. For tours, in which the exhibit includes buildings or public art, for instance, alternative audio tracks can be provided that are adapted to environmental noise factors such as whether the user is walking or riding and whether the user is visiting during a quiet or noisy time of day. Different exhibits can receive different treatments, depending on the particular environmental noise factors at the locations where they are viewed. So adaptation to environmental factors may be specific to particular segments of a tour.

Audio reproduction features also may justify alternative sound tracks. For instance, the audio systems of laptop computers and computer monitors have attenuated low frequency response that can be compensated for with an alternate sound track. In other audio systems, high or mid-tone frequencies may be attenuated.

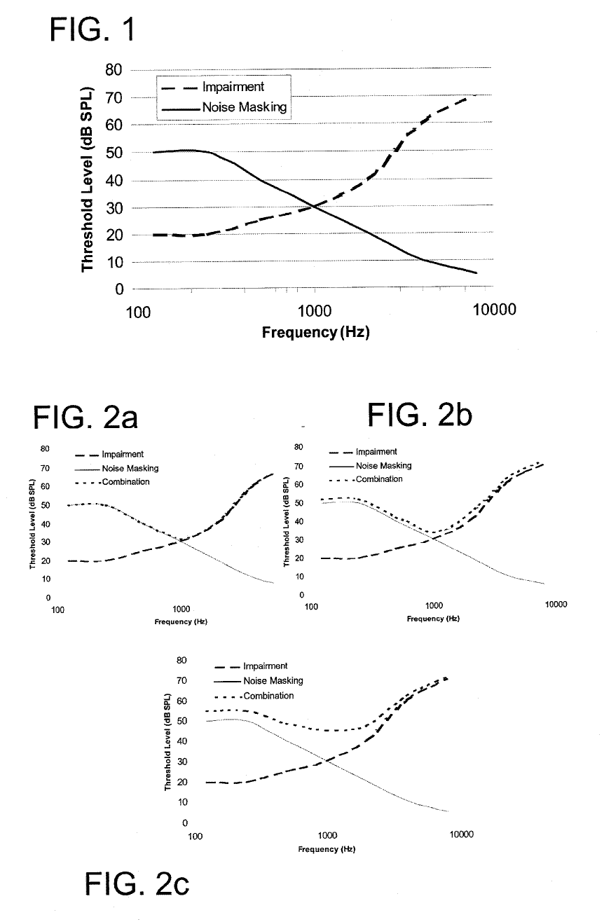

FIGS. 1 and 2a-c illustrate the application of amplitude compression to overcome hearing loss, environmental, and other auditory factors. Hearing loss can be characterized by an increased threshold for perceiving an audio signal. At any given frequency, the threshold of audibility of a tone can be elevated by a hearing loss at that frequency and by masking of that frequency by competing noise. For normal hearing listeners, the amount of masking at any frequency can be calculated by filtering the amount of noise power out of an auditory filter centered at the frequency of interest. For hearing loss listeners, the hearing loss and the masking from the noise combine to reduce audibility. Accurately determining the combined result of these two effects is useful, in order to properly set the parameters of the signal processing algorithm that compensates for reduced audibility, but not essential to the present invention. Given the spectral density of a noise, the masked threshold can be calculated for someone with normal hearing by the application of normal auditory filters. The masked threshold of someone with a hearing impairment will depend on the combination of the masking level of the noise and the level of the impairment at each frequency. The threshold from the combined effect (THtot) should be predictable from the threshold due to the impairment (THi) and the masked threshold for normals (THm). In alternative systems, the threshold due to impairment THi could be replaced by, or supplemented with, a threshold parameter THc provided in response to information about a users personal choice, where the subscript “c” represents personal choice for profile.

The solid line in FIG. 1 shows a hypothetical sloped hearing loss and the dashed line shows a hypothetical masked threshold for someone with normal hearing resulting from noise. In this example, and in general, noise dominates audibility in the low frequencies and hearing loss dominates audibility in the high frequencies.

Three formulas that combine the hearing loss threshold and the normal masked threshold effects are demonstrated in FIGS. 2a-c. Simply taking the maximum of either threshold function as the combined threshold is shown in FIG. 2a. This function is represented by

THtot=max(THi,THm)

and is depicted by the dotted line, which has been displaced upwards by 1 dB in order to see the curve in the presence of the other two.

A second possibility is shown by the dotted line in FIG. 2b and results from summing the powers of each threshold. This is represented by

THtot=10log10[10\hat{ }(THi/10)+10\hat{ }(THm/10)].

With this function, the combined effect is primarily to take the maximum threshold, except in the region where the thresholds are equal, where there is an elevating of the combined threshold.

A third implementation takes into account the compressive properties of the auditory system. This is demonstrated with the dotted line in FIG. 2c and is represented by

THtot=10log10[{10\hat{ }(p*THi/10)+10\hat{ }(*THm/10)−10\hat{ }(p*THn/10)}\hat{ }(1/p)]

Where THn is the threshold of the normal hearing listener. This function is from Jesteadt et al. (1995). The parameter p represents the amount of compression used during the summation and in the example given has a value of 0.2. This method of calculating the combined effect is consistent with experimental data obtained with hearing impaired subjects.

As mentioned before, THc could also be used in these and similar equations for providing an effective combined profile for preprocessing adapted to a noisy environment.

The effect of environmental noise on auditory perception is to reduce the dynamic range available for sounds above the masking level of the environmental noise and to cause abnormal loudness perception of sound heard simultaneously with the noise. Sound ID's Full Frequency Dynamic Compression (FFDC) is one system that replicates the compressive function of the healthy cochlea, compressing sound such that the audio signal is no longer distorted in the auditory system and perception is restored to normal.

Customization techniques applying amplitude compression can be adapted to generate preprocessed alternative sound tracks for DVDs and other recording media. Hypothetical hearing losses and masking noise effects such as those of FIGS. 1 and 2a-c can be predetermined to establish one or more standard preprocessing profiles. These profiles might match mild, moderate and severe hearing loss of flat and sloped profiles. They might match masking noises of car, minivan, bus, train, turboprop, jet transportation or any other environment. Combined standard profiles can be generated for significant industry segments, such as jet transportation. These standard profiles can take into account both environment and a variety of hearing loss conditions. Or, for a specific hearing loss condition, combined standard profiles can be generated for a variety of environmental conditions. Other auditory factors, in addition to hearing loss and environmental noise factors, also can be taken into account. These other auditory factors include audio systems where low frequency sounds are significantly attenuated, such as audio output built into laptop computers or into computer monitors.

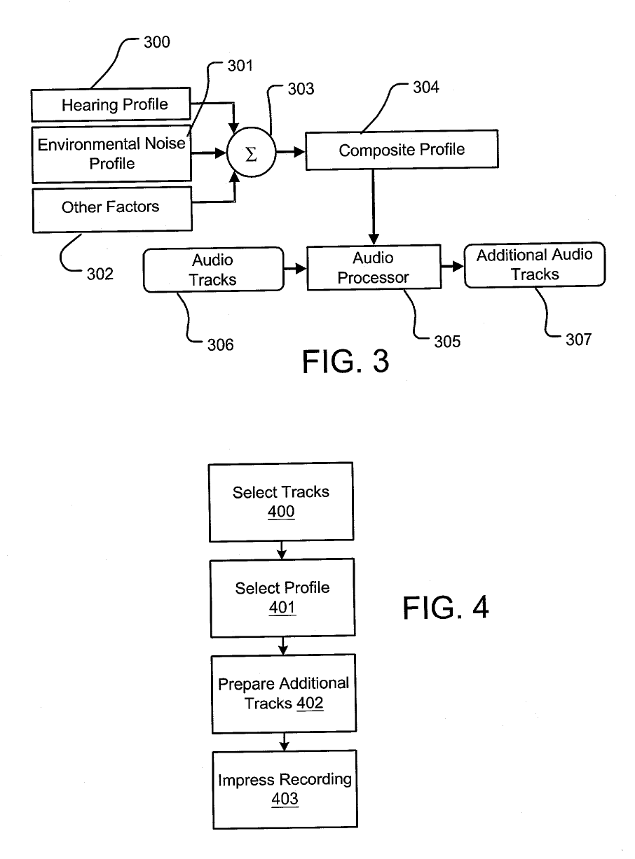

FIG. 3 illustrates how a hearing profile 300, a profile of environmental noise 301 and an additional auditory factor 302 can be combined in a variety of ways represented by the summing node 303 into a composite or resultant profile 104 to generate an additional audio track. All three sub-profiles are not necessarily active at all times. As shown in FIG. 3, an audio processor 305 in an encoding device receives the composite or resultant profile 304, and applies the profile 304 to a source audio stream 306, to apply amplitude compression and provide an additional audio track 307, which enhances the user's reception of the audio product. The summing node 303 is used heuristically in the diagram. In various embodiments, each component 300, 301, 302 of the composite profile 304 can be used independently, in series, or in parallel in any combination to apply multiband amplitude compression. In one preferred embodiment, the additional audio track is impressed on a DVD, CD or other recording media as a selectable track.

The present invention can produce a recorded medium that does not depend on any special playback equipment to accommodate hearing loss, environmental or other auditory factors. The preparation of an additional audio track need not be designed to match any playback circuit for amplitude compression. Instead, the amplitude compression is accomplished by preprocessing the signal, before impressing the additional sound track onto the recording medium. The user can select either the original or the additional sound track, to match their hearing condition and environmental or other factors.

Additional equipment can be combined with preprocessing of additional audio tracks. This additional equipment can require the user to log on, triggering a hearing condition look up, or can sense the environmental condition, for instance using as a loudness control setting or a microphone to detect background noise. Additional equipment can select among additional sound tracks automatically, based on the user log-on or id and the detected environmental conditions.

FIG. 4 illustrates methods practicing the present invention including methods for manufacturing a multimedia recording or for manufacturing an alternative track audio recording, either recording adapted to one or more of hearing impairment, environmental factors or other auditory factors. For multimedia recording, one action required is to select one or more synchronized visual and audio tracks for preprocessing 400. For alternative sound-track recording, one or more audio tracks would be selected for preprocessing 400. Next, a multi-band amplitude compression profile is selected 401. This profile may compensate for hearing impairment. It may compensate for environmental factors, or it may compensate for auditory factors other than hearing impairment or environmental. The multi-band amplitude compression profile also may compensate for a combination of factors. The selected multi-band amplitude compression profile is applied to the one or more audio tracks to produce one or more additional compressed audio tracks so that compressed audio can be played back with equipment lacking compression ability. The additional audio tracks are impressed on to a recording medium 403. The recording medium may be a DVD, a compact disc, mini disc, memory card or some other recording medium. Preferably, it is a widely accepted, standard recording medium, for which typical consumer-oriented playback equipment allows selection among multiple audio tracks. A further aspect of the present invention is an article of manufacture that results from these or equivalent methods.

An article of manufacture practicing aspects of the present invention may include both visual and audio or just alternative audio tracks. For a multimedia article of manufacture, synchronized visual and audio tracks are included, plus one or more additional audio tracks, which have been preprocessed with the multi-band amplitude compression profile. As above, the multi-band amplitude compression profile may be adapted to compensate for one or more of hearing impairment, environmental factors, or other auditory factors. The recording medium may be a DVD, compact disc or other recording medium. The article of manufacture includes one or more additional audio tracks adapted for playback on equipment lacking signal-processing capabilities intended to compensate for hearing loss, environmental noise, or a combination of both. The present methods and articles of manufacture are considered compatible with and distinct from general-purpose encoding schemes such as MPEG-2, Mini-Disc, Dolby-NR, Dolby Pro Logic or Dolby AC-3. These general-purpose encoding schemes utilize special matched encoding and decoding hardware or software to reduce data rates or the transmission of noise. In contrast, the method described here encodes the signal through multi-band amplitude compression in a way that is approximately inverse to the “decoding” process of the impaired ear or the normal ear operating in the process of environmental noise. It is important to note that the decoding is achieved in the ear and not through signal-processing means. The lack of decoding means distinguishes the current algorithm from encoding schemas such as MPEG-2, Mini-Disc, Dolby-NR, Dolby Pro Logic and Dolby AC-3.

While the present invention is disclosed by reference to the preferred embodiments and examples detailed above, it is understood that these examples are intended in an illustrative rather than in a limiting sense. It is contemplated that modifications and combinations will readily occur to those skilled in the art, which modifications and combinations will be within the spirit of the invention and the scope of the following claims.

We claim as follows:

1. A method of manufacturing a multimedia recording adapted to hearing impairment, environmental noise or other auditory factors, including:
selecting material including one or more synchronized visual and audio tracks;
selecting one or more multi-band amplitude compression profiles;
applying multi-band amplitude compression processing according to the set of profiles to the one or more synchronized audio tracks, preserving the synchronization, to generate a set of one or more additional audio tracks adapted for playback on equipment lacking signal-processing capabilities designed to enhance audibility through multi-band amplitude compression; and
impressing the synchronized visual and audio tracks and the additional audio tracks onto a recording medium.

2. The method of claim 1, wherein the amplitude compression profile is adapted to compensate for hearing impairment.

3. The method of claim 1, wherein the amplitude compression profile is adapted to compensate for environmental noise factors.

4. The method of claim 1, wherein the amplitude compression profile is adapted to compensate for audio reproduction features.

5. The method of claim 1, wherein the amplitude compression profile is adapted to compensate for auditory factors other than hearing impairment or environmental noise factors.

6. The method of claim 1, wherein the recording medium is a DVD.

7. The method of claim 1, wherein the recording medium is a compact disk.

8. The method of claim 1, wherein the recording medium is a mini-disc.

9. The method of claim 1, wherein the recording medium is solid-state memory.

10. An article of manufacture, adapted to compensate for hearing impairment, environmental noise or other auditory factors, including:
one or more synchronized visual and audio tracks;
one or more additional audio tracks, the additional audio tracks being multi-band amplitude compressed variations on the synchronized audio tracks adapted for playback on equipment lacking signal-processing capabilities designed to enhance audibility through multi-band amplitude compression; and
a recording medium, on which the synchronized visual and audio tracks and the additional audio tracks are stored, the synchronized audio tracks and the additional audio tracks being selectable.

11. The article of claim 10, wherein the amplitude compression profile is adapted to compensate for hearing impairment.

12. The article of claim 10, wherein the amplitude compression profile is adapted to compensate for environmental noise factors.

13. The method of claim 10, wherein the amplitude compression profile is adapted to compensate for audio reproduction features.

14. The article of claim 10, wherein the amplitude compression profile is adapted to compensate for auditory factors other than hearing impairment or environmental noise factors.

15. The article of claim 10, wherein the recording medium is a DVD.

16. The article of claim 10, wherein the recording medium is a compact disk.

17. The article of claim 10, wherein the recording medium is a mini-disc.

18. The article of claim 10, wherein the recording medium is solid-state memory.

19. A method of manufacturing a tour-synchronized recording adapted to hearing impairment, environmental noise or other auditory factors, including:
selecting material including one or more audio tracks synchronized to a tour;
selecting one or more multi-band amplitude compression profiles;
applying multi-band amplitude compression processing according to the set of profiles to the one or more synchronized audio tracks, preserving the synchronization, to generate a set of one or more additional audio tracks adapted for playback on equipment lacking signal-processing capabilities designed to enhance audibility through multi-band amplitude compression; and
impressing the synchronized audio tracks and the additional audio tracks and synchronization data onto a recording medium.

20. The method of claim 19, wherein the amplitude compression profile is adapted to compensate for hearing impairment.

21. The method of claim 19, wherein the amplitude compression profile is adapted to compensate for environmental noise factors.

22. The method of claim 19, wherein the amplitude compression profile is adapted to compensate for audio reproduction features.

23. The method of claim 19, wherein the amplitude compression profile is adapted to compensate for auditory factors other than hearing impairment or environmental noise factors.

24. The method of claim 19, wherein the recording medium is a DVD.

25. The method of claim 19, wherein the recording medium is a compact disk.

26. The method of claim 19, wherein the recording medium is a mini-disc.

27. The method of claim 19, wherein the recording medium is solid-state memory.

28. The method of claim 19, wherein the synchronization data links the synchronized audio tracks to one or more locations.

29. The method of claim 19, wherein the synchronization data links the synchronized audio tracks to one or more visual stimuli.

30. An article of manufacture, adapted to compensate for hearing impairment, environmental noise or other auditory factors, including:
one or more audio tracks synchronized to a tour;
one or more additional audio tracks, the additional audio tracks being multi-band amplitude compressed variations on the synchronized audio tracks adapted for playback on equipment lacking signal-processing capabilities designed to enhance audibility through multi-band amplitude compression; and
a recording medium, on which the synchronized audio tracks and the additional audio tracks and synchronization data are stored, the audio tracks and the additional audio tracks being selectable.

31. The article of claim 30, wherein the amplitude compression profile is adapted to compensate for hearing impairment.

32. The article of claim 30, wherein the amplitude compression profile is adapted to compensate for environmental noise factors.

33. The method of claim 30, wherein the amplitude compression profile is adapted to compensate for audio reproduction features.

34. The article of claim 30, wherein the amplitude compression profile is adapted to compensate for auditory factors other than hearing impairment or environmental noise factors.

35. The article of claim 30, wherein the recording medium is a DVD.

36. The article of claim 30, wherein the recording medium is a compact disk.

37. The article of claim 30, wherein the recording medium is a mini-disc.

38. The article of claim 30, wherein the recording medium is solid-state memory.

39. The method of claim 30, wherein the synchronization data links the synchronized audio tracks to one or more locations.

40. The method of claim 30, wherein the synchronization data links the synchronized audio tracks to one or more visual stimuli.

41. A method of manufacturing an alternative tracks recording adapted to hearing impairment, environmental noise or other auditory factors, including:
selecting material including one or more audio tracks;
4 selecting one or more a multi-band amplitude compression profiles;
applying multi-band amplitude compression processing according to the set of profiles to the one or more audio tracks to generate a set of one or more additional audio tracks adapted for playback on equipment lacking signal-processing capabilities designed to enhance audibility through multi-band amplitude compression; and
impressing the audio tracks and the additional audio tracks onto a recording medium.

42. The method of claim 41, wherein the amplitude compression profile is adapted to compensate for hearing impairment.

43. The method of claim 41, wherein the amplitude compression profile is adapted to compensate for environmental noise factors.

44. The method of claim 41, wherein the amplitude compression profile is adapted to compensate for audio reproduction features.

45. The method of claim 41, wherein the amplitude compression profile is adapted to compensate for auditory factors other than hearing impairment or environmental noise factors.

46. The method of claim 41, wherein the recording medium is a DVD.

47. The method of claim 41, wherein the recording medium is a compact disk.

48. The method of claim 41, wherein the recording medium is a mini-disc.

49. The method of claim 41, wherein the recoding medium is solid-state memory.

50. An article of manufacture, adapted to compensate for hearing impairment, environmental noise or other auditory factors, including:
one or more audio tracks;
one or more additional audio tracks, the additional audio tracks being multi-band amplitude compressed variations on the audio tracks adapted for playback on equipment lacking signal-processing capabilities designed to enhance audibility through multi-band amplitude compression; and
a recording medium, on which the audio tracks and the additional audio tracks are stored, the audio tracks and the additional audio tracks being alternatively selectable.

51. The article of claim 50, wherein the amplitude compression profile is adapted to compensate for hearing impairment.

52. The article of claim 50, wherein the amplitude compression profile is adapted to compensate for environmental noise factors.

53. The method of claim 50, wherein the amplitude compression profile is adapted to compensate for audio reproduction features.

54. The article of claim 50, wherein the amplitude compression profile is adapted to compensate for auditory factors other than hearing impairment or environmental noise factors.

55. The article of claim 50, wherein the recording medium is a DVD.

56. The article of claim 50, wherein the recording medium is a compact disk.

57. The article of claim 50, wherein the recording medium is a mini-disc.

58. The article of claim 50, wherein the recording medium is solid-state memory.
